(19) United States
(12) Patent Application Publication
(10) Pub. No.: US 2002/0155668 A1
(43) Pub. Date: Oct. 24, 2002

(54) Method of reducing leakage current in a MOS transistor

(76) Inventor: Chien-Hsing Lin, Taichung City (TW)

Correspondence Address: NAIPO (NORTH AMERICA INTERNATIONAL PATENT OFFICE), P.O. BOX 506, MERRIFIELD, VA, 22116, US

(21) Appl. No.: 09/836,207

(22) Filed: Apr. 18, 2001

(51) Int. Cl. H01L 21/336

(52) U.S. Cl. 438/296; 438/305

(57) ABSTRACT

A method of reducing leakage current in a metal-oxide semiconductor (MOS) transistor is employed on a semiconductor wafer, having a substrate, the MOS transistor and a shallow trench isolation (STI) structure adjacent to the MOS transistor on a wafer surface. The method is employed to form a gettering region within the STI structure to getter metal ions diffusing from a silicide layer so as to reduce leakage current in the MOS transistor.

### BACKGROUND OF THE INVENTION

1. Field of the invention

The present invention relates to a method of reducing leakage current in a metal-oxide semiconductor (MOS) transistor, and more specifically, to a method of reducing leakage current in a MOS transistor by forming a gettering region within a shallow trench isolation (STI) structure.

2. Description of the Prior Art

A metal-oxide semiconductor (MOS) is a common electrical device used in integrated circuits. The MOS transistor is a unit, having four nodes, formed by a gate, a source and a drain. By utilizing channel effects generated by the gate of the MOS under different gate voltages, the MOS is often made to function as a digitalized solid switch applied on various integrated circuits of memory or logic devices.

Please refer to FIG. 1 to FIG. 4 of the cross-sectional views of manufacturing a MOS transistor with a shallow trench isolation (STI) structure according to the prior art. As shown in FIG. 1, a silicon substrate 12, a gate oxide layer 14 and a gate 16 are formed, respectively, on a semiconductor wafer 10. A STI structure 19, comprising a liner oxide layer 20 and a dielectric layer 21, used for filling the STI structure, is further formed in portions of the silicon substrate 12 in a predetermined distance from the gate 16.

As shown in FIG. 2, a first ion implantation process 18 is performed to form two doped areas, used as a lightly doped drain (LDD) 22 of the MOS transistor, positioned on either side of the gate 16 on the surface of the silicon substrate 12. The LDD 22 is also called a source-drain extension (SDE).

As shown in FIG. 3, a spacer 24, composed of an insulating material, is then formed on either vertical wall of the gate 16. As shown in FIG. 4, a second ion implantation process 26 is performed to form two doped areas, used as a source 27 and a drain 28 of the MOS transistor, positioned on portions of the silicon substrate 12 adjacent to the spacer 24 at the end of the formation of the MOS transistor.

Please refer to FIG. 5 of a cross-sectional view of performing a self-alignment silicide process on a MOS transistor.

The self-alignment silicide (salicide) process is normally performed after the formation of the MOS transistor to reduce the contact resistance of each silicon surface on the MOS transistor. Normally a metal layer, composed of cobalt (Co), nickel (Ni), titanium (Ti) or tungsten (W), is formed on the silicon surfaces of the gate 16, the source 27 and the drain 28 by performing a sputtering process. A thermal process is then performed to induce a reaction between metal atoms in the metal layer and the silicon atoms on the surfaces of the gate 16, the source 27 and the drain 28 so as to form a silicide layer 32.

However, the sputtering process employed to form a metal layer, composed of Co, Ni, Ti or W, on the silicon surfaces of the gate 16, the source 27 and the drain 28 normally causes mobile electrons and metal ions to reside on the surfaces of the gate 16, the source 27 and the drain 28. The reverse leakage current and the static power dissipation are thus increased. Besides, the residual electrons and ions can further diffuse into the source 27/drain 28 and accumulate on the interface between the source 27/drain 28 and the silicon substrate 12 so as to result in a decreased junction breakdown voltage, leading to the malfunction of the device.

### SUMMARY OF THE INVENTION

It is therefore a primary object of the present invention to provide a method of forming a gettering region within a shallow trench isolation (STI) structure adjacent to a metal-oxide semiconductor (MOS) transistor to trap electrons and mobile ions in a semiconductor wafer so as to reduce leakage current in the MOS transistor.

According to the claimed invention, a MOS transistor and a STI structure adjacent to the MOS transistor are positioned on a substrate of a semiconductor wafer. An ion implantation process is performed to form a gettering region within the STI structure to getter electrons and mobile ions in the semiconductor wafer. The leakage current in the MOS transistor is thus reduced.

It is an advantage of the present invention that a gettering region is formed by performing both an ion implantation process, using phosphorous ions as the dosage, and an annealing process. The mobile electrons and metal ions diffused from the salicide layer are thus gettered so as to prevent the decreased junction breakdown voltage caused by the electrons and ions accumulated on the interface between the source/drain and the silicon substrate. Besides, negative effects, including static power dissipation and reverse leakage, caused by residual electrons and ions can be prevented as well. Consequently, the reliability and the performance of the MOS transistor can be significantly improved.

These and other objectives of the present invention will no doubt become obvious to those of ordinary skill in the art after reading the following detailed description of the preferred embodiment, which is illustrated in the multiple figures and drawings.

### BRIEF DESCRIPTION OF THE DRAWING

FIG. 1 to FIG. 4 are cross-sectional views of manufacturing a MOS transistor with a STI structure according to the prior art.

FIG. 5 is a cross-sectional view of performing a self-alignment silicide process on a MOS transistor.

FIG. 6 to FIG. 11 are cross-sectional views of manufacturing a MOS transistor with a STI structure according to the present invention.

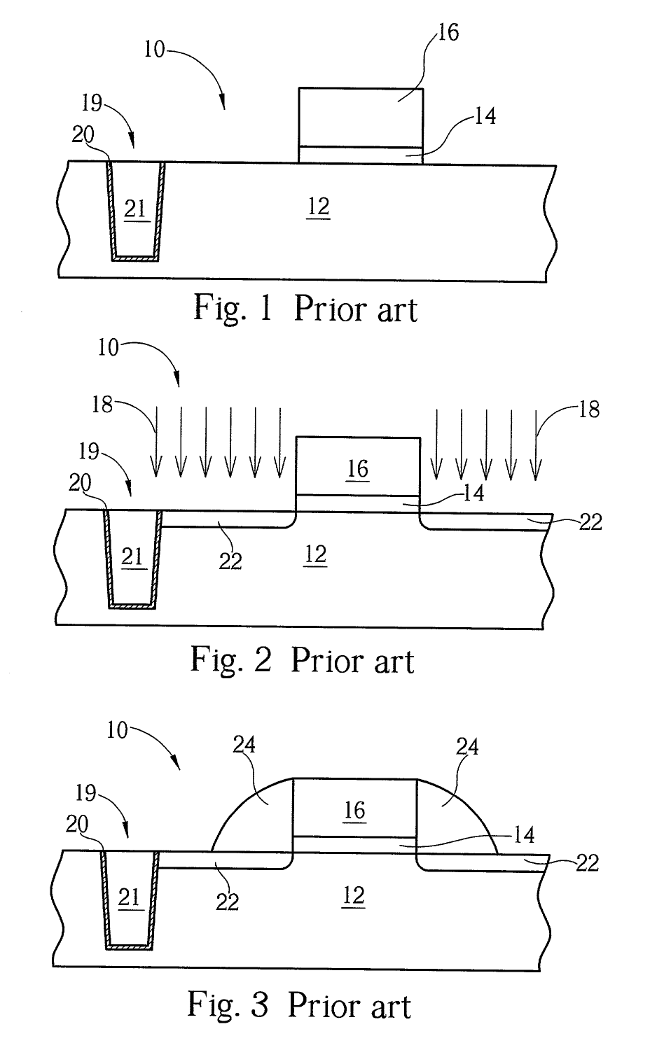

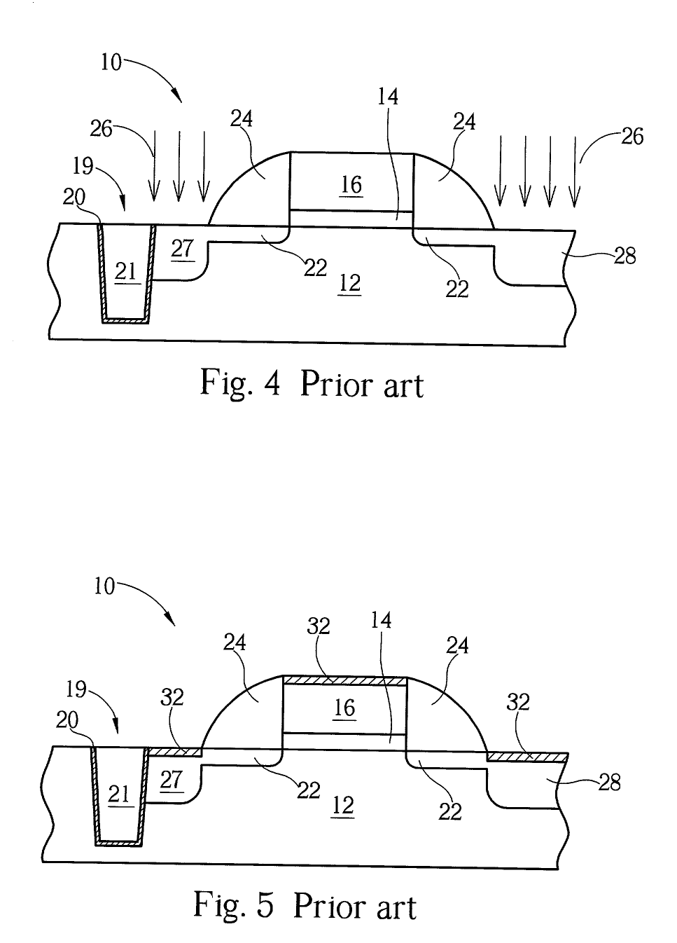

### DETAILED DESCRIPTION OF THE PREFERRED EMBODIMENT

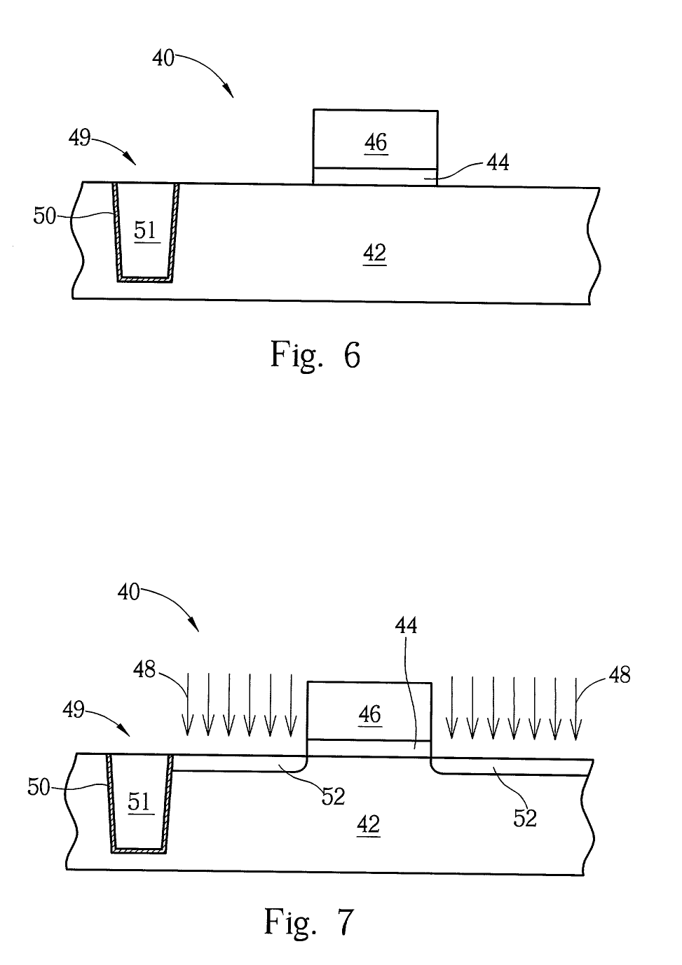

Please refer to FIG. 6 to FIG. 11 of the cross-sectional views of manufacturing a metal-oxide semiconductor (MOS) transistor with a shallow trench isolation (STI) structure according to the present invention. As shown in FIG. 6, a silicon substrate 42 of p-type and at least one gate 46, with an underlying gate oxide layer 44 are formed, respectively, on a semiconductor wafer 40. A STI structure 49, comprising a liner oxide layer 50 and a dielectric layer 51 employed to fill the STI structure, is further formed in portions of the silicon substrate 42 at a predetermined distance from the gate 46.

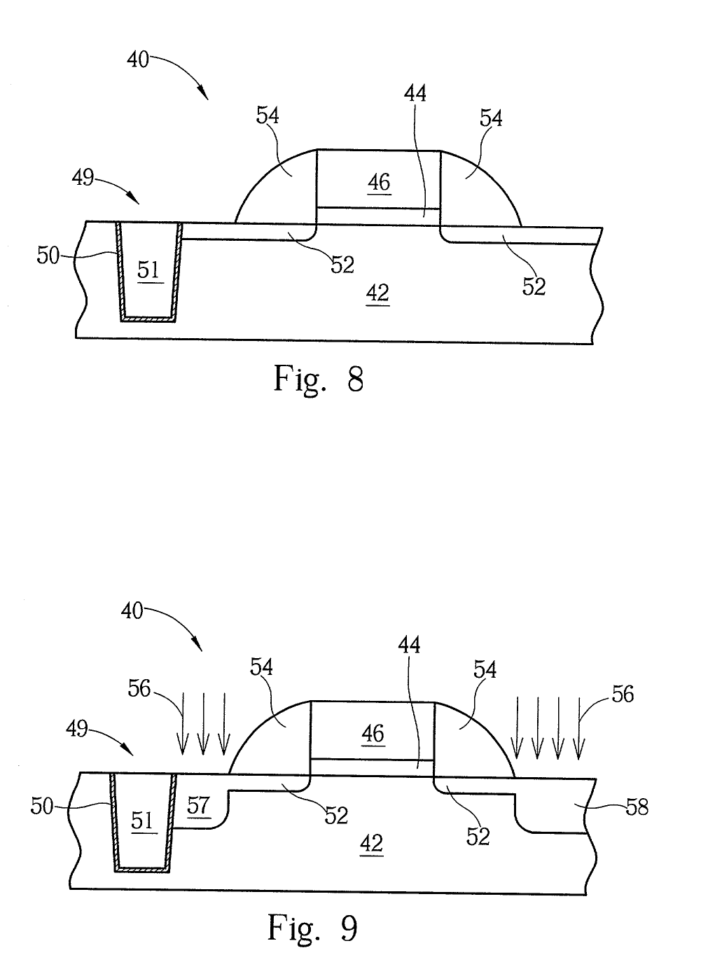

As shown in FIG. 7, a first ion implantation process 48 is performed to form two doped areas, used as a lightly doped drain (LDD) 52 of the MOS transistor, positioned on either side of the gate 46 on the surface of the silicon substrate 42. The LDD 22 is also called a source-drain extension (SDE) . As shown in FIG. 8, a spacer 54, comprised of an insulating material, is then formed on either vertical wall of the gate 46. As shown in FIG. 9, a second ion implantation process 56 is performed to form two doped areas, used as a source 57 and a drain 58 of the MOS transistor, positioned in portions of the silicon substrate 42 adjacent to the spacer 54.

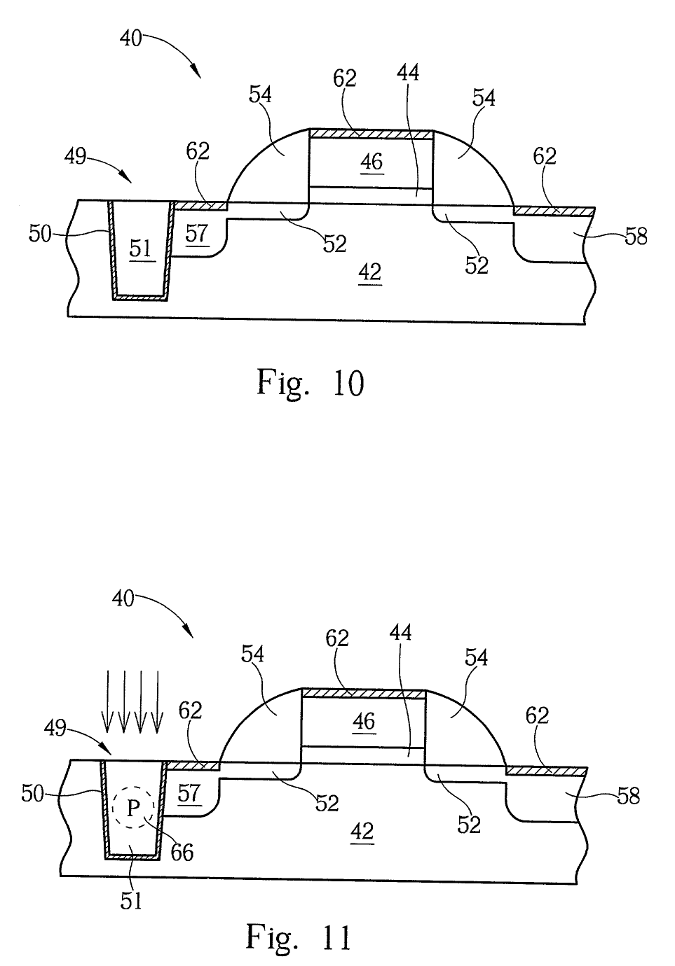

As shown in FIG. 10, a self-alignment silicide (salicide) process is normally performed after the formation of the MOS transistor to reduce the contact resistance of each silicon surface on the MOS transistor. Normally a metal layer, composed of cobalt (Co), nickel (Ni), titanium (Ti) or tungsten (W), is formed on the silicon surfaces of the gate 46, the source 57 and the drain 58 by performing a sputtering process. A thermal process is then performed to induce a reaction between metal atoms in the metal layer and the silicon atoms on the surfaces of the gate 46, the source 57 and the drain 58. A silicide layer 62, leading to a reduced contact resistance of each silicon surface on the MOS transistor, is thus formed.

Finally, as shown in FIG. 11, a third ion implantation process 64, using phosphorous ions (P) as a dosage, is performed to implant phosphorous ions into the STI structure 49. Immediately an annealing process is performed to cause the implanted phosphorous ions to form a gettering region 66 within the STI structure 49 to getter mobile electrons and metal ions so as to reduce leakage current in the MOS transistor.

Alternatively, the third ion implantation process 64 can be performed prior to the salicide process. Phosphorous ions can be immediately implanted into the STI structure 49 after the LDD 52 is formed. The annealing process is then performed with the driving-in process of the LDD 52, the source 57 and the drain 58 to form the gettering region 66. Mobile electrons and metal ions in the subsequent sputtering process employed to form the metal layer, composed of Co, Ni, Ti or W, are thus gettered.

In comparison with the prior art, a gettering region is formed by performing both an ion implantation process, using phosphorous ions as the dosage, and an annealing process in the present invention. The mobile electrons and metal ions diffused from the salicide layer are thus gettered so as to prevent static power dissipation and reverse leakage. Besides, by trapping the electrons and ions diffused from the salicide layer, the decreased junction breakdown voltage, caused by the electrons and ions accumulated on the interface between the source/drain and the silicon substrate, is prevented as well. Therefore, the reliability and the performance of the MOS transistor can be significantly improved.

Those skilled in the art will readily observe that numerous modifications and alterations of the device may be made while retaining the teachings of the invention. Accordingly, the above disclosure should be construed as limited only by the metes and bound of the appended claims.

What is claimed is:

1. A method of reducing leakage current in a metal-oxide semiconductor (MOS) transistor on a semiconductor wafer, the semiconductor wafer comprising a substrate, a shallow trench isolation (STI) structure positioned in the substrate, and a MOS transistor positioned on the substrate adjacent to the STI structure, the MOS transistor comprising a gate, and a source and a drain respectively positioned in the substrate adjacent to opposite sides of the gate, the method comprising:
forming a silicide layer on top of the gate, on the surface of the source, and on the surface of the drain;
performing an ion implantation process to implant phosphorous ions into the STI structure; and
performing an annealing process to cause the phosphorous ions to form a gettering region within the STI structure to getter metal ions diffusing from the silicide layer so as to reduce leakage current in the MOS transistor.

2. The method of claim 1 wherein the gate comprises a gate oxide layer and a gate electrode positioned on the gate oxide layer.

3. The method of claim 1 wherein the MOS transistor further comprises a spacer positioned around the gate, and a lightly doped drain (LDD) positioned in the substrate adjacent to the gate.

4. A method of reducing leakage current in a metal-oxide semiconductor (MOS) transistor on a semiconductor wafer, the semiconductor wafer comprising a substrate, a MOS transistor positioned on the substrate, and a shallow trench isolation (STI) structure positioned in the substrate around the MOS transistor, the method comprising:
performing an ion implantation process to form a gettering region within the STI structure to trap electrons and mobile ions in the semiconductor wafer so as to reduce leakage current in the MOS transistor.

5. The method of claim 4 wherein the MOS transistor comprises a gate, and a source and a drain respectively positioned in the substrate adjacent to opposite sides of the gate, the gate comprising a gate oxide layer and a gate electrode positioned on the gate oxide layer.

6. The method of claim 5 wherein the MOS transistor further comprises a spacer positioned around the gate, a lightly doped drain (LDD) positioned in the substrate adjacent to the gate, and a silicide layer positioned on top of the gate, on the surface of the source and on the surface of the drain.

7. The method of claim 4 wherein the ion implantation process uses phosphorous as an ion source.

8. The method of claim 4 wherein the method further comprises an annealing process following the ion implantation process to cause the ions implanted by the ion implantation process to form the gettering region in the STI structure.
